(19) United States
(12) Patent Application Publication
(10) Pub. No.: US 2007/0228356 A1
(43) Pub. Date: Oct. 4, 2007

(54) ORGANIC-INORGANIC COMPOSITE SEMICONDUCTOR MATERIAL, LIQUID MATERIAL, ORGANIC LIGHT EMITTING ELEMENT, METHOD OF MANUFACTURING ORGANIC LIGHT EMITTING ELEMENT, LIGHT EMITTING DEVICE AND ELECTRONIC APPARATUS

(75) Inventors: Rie Makiura, Suwa-shi (JP); Tomoyuki Okuyama, Chino-shi (JP); Takeo Kawase, Suwa-shi (JP); Mitsuharu Noto, Kurume-shi (JP); Tsuyoshi Hayashida, Tosu-shi (JP); Yasuyuki Goto, Fukuoka-shi (JP)

Correspondence Address: OLIFF & BERRIDGE, PLC, P.O. BOX 19928, ALEXANDRIA, VA, 22320, US

(73) Assignees: Seiko Epson Corporation, Tokyo (JP); Dyden Corporation, Kurume-city (JP); Kyushu Electric Power Company, Incorporated, Fukuoka (JP)

(21) Appl. No.: 11/691,832

(22) Filed: Mar. 27, 2007

(30) Foreign Application Priority Data
Apr. 3, 2006 (JP) 2006-102556

(51) Int. Cl. H01L 29/06; H01L 33/00

(52) U.S. Cl. 257/13; 257/79; 257/80

(57) ABSTRACT

Organic-inorganic composite semiconductor material including material mainly made of at least one kind of a metal ion selected from an alkali metal ion, an alkali earth metal ion and a rare-earth metal ion, and a chemical compound represented by the following general formula (1): 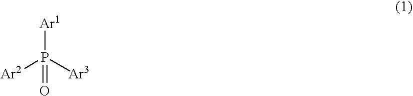
where Ar¹, Ar² and Ar³ are each independently an aromatic ring group that optionally has a substituent group.

### BACKGROUND OF THE INVENTION

1. Technical Field

Several aspects of the present invention relate to organic-inorganic composite semiconductor material, liquid material, an organic light emitting element, a method for manufacturing an organic light emitting element, a light emitting device and an electronic apparatus.

2. Related Art

As organic semiconductor elements made of an organic semiconductor material or an organic semiconductor material and an organic/inorganic composite semiconductor material combined, there are organic light emitting elements, organic transistors, solar cells and the like for example

With an organic electroluminescence (EL) element that has a light emissive organic layer (an organic electroluminescence layer) between an anode and a cathode, it is possible to significantly lower the voltage applied to the organic EL element compared with that of an inorganic EL element. Furthermore, the organic EL element makes it possible to fabricate various light emitting elements with various emission colors.

In order to obtain an organic EL with a higher efficiency, a device structure including various layers provided between a cathode and a light emissive organic layer (an emissive layer) or/and between an anode and an organic light emissive layer has been proposed recently and such structure is now actively researched.

Such layers include an electron transport layer provided between the cathode and the organic light emissive layer, an electron injection layer provided between the electron transport layer and the cathode and the like. Because the qualities of the electron transport layer and the electron injection layer largely affect the quality of the device, some improvement should be made to the qualities of these layers as early as possible.

JP-A-2005-63910 is an example of related art. The example proposes a structure that improves the quality of the electron injection layer. The structure has a metal compound mixed in the electron injection layer. The metal compound is mixed in such a way that an organic compound having an electron transport property and a metal compound containing an alkali metal that is a low work function metal are co-deposited.

The electron injection layer having such structure was developed aiming for a low driving voltage and an improved luminous efficiency, and it is hardly improved in terms of durability. According to the example, the electron injection layer was formed by a vacuum deposition method which needs large scale equipment. Moreover, it is difficult to accurately adjust the deposition speed when two or more kinds of materials are simultaneously deposited, this leads to a low productivity.

### SUMMARY

An advantage of the present invention is to provide an organic-inorganic composite semiconductor material having a high electron injection property and a high electron transport property, a liquid material of which such organic-inorganic composite semiconductor material is solved in a solvent, and an organic light emitting element with a high luminous efficiency and a fine durability made of the organic-inorganic composite semiconductor material thereof. Another advantage of the invention is to provide with a high a productive manufacturing method of such organic light emitting element, and a reliable light emitting device and a reliable electronic apparatus having such organic light emitting element.

Organic-inorganic composite semiconductor material according to a first aspect of the invention includes a material mainly made of at least one kind of a metal ion selected from an alkali metal ion, an alkali earth metal ion and a rare-earth metal ion, and a chemical compound represented by the following general formula (1): 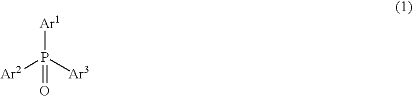
where Ar¹, Ar² and Ar³ are each independently an aromatic ring group that optionally has a substituent group.

In this way, it is possible to obtain the organic-inorganic composite semiconductor material having a high electron injection property, a high electron transport property, a fine durability and a long lifetime.

In this case, it is preferable that the Ar¹, Ar² and Ar³ in the chemical compound represented by the general formula (1) be a phenyl group that has a substituent group.

In this way, it is possible to obtain the organic-inorganic composite semiconductor material having a higher electron injection property, a higher electron transport property, a fine durability and a longer lifetime.

It is preferable that the substituent group of the Ar¹, Ar² and Ar³ be a group represented by the following general formula (2): 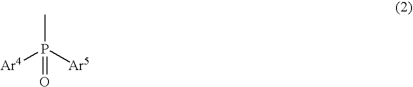
where Ar⁴ and Ar⁵ are each independently an aromatic ring group that optionally has a substituent group.

In this way, it is possible to obtain the organic-inorganic composite semiconductor material having a higher electron injection property, a higher electron transport property, a fine durability and a longer lifetime.

It is preferable that the Ar⁴ and Ar⁵ in the substituent group represented by the general formula (2) be a phenyl group.

In this way, it is possible to obtain the organic-inorganic composite semiconductor material having a higher electron injection property, a higher electron transport property, a fine durability and a longer lifetime.

It is preferable that a quantitative ratio “B/A” of the compound represented by the general formula (1) to the metal ion be 0.05 or more, where the number of P═O bonds in the compound represented by the general formula (1) is denoted as “A” and the number of the metal ion is denoted as “B”.

In this way, it is possible to obtain the organic-inorganic composite semiconductor material having a higher electron injection property, a higher electron transport property, a fine durability and a longer lifetime.

It is preferable that a quantitative ratio “B/A” of the compound represented by the general formula (1) to the metal ion be 0.2 or more, where the number of P═O bonds in the compound represented by the general formula (1) is denoted as “A” and the number of the metal ion is denoted as “B”.

In this way, it is possible to obtain the organic-inorganic composite semiconductor material having a higher electron injection property, a higher electron transport property, a fine durability and a longer lifetime.

An organic light emitting element according to a second aspect of the invention includes an anode, an organic light emissive layer provided on one side of the anode, an electron transport layer provided on the organic light emissive layer and a cathode provided on a side of the electron transport layer opposite to the organic light emissive layer, wherein the electron transport layer is mainly made of a material containing at least one kind of a metal ion selected from an alkali metal ion, an alkali earth metal ion and a rare-earth metal ion, and a chemical compound represented by the following general formula (1): 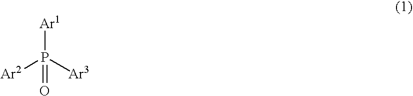
where Ar¹, Ar² and Ar³ are each independently an aromatic ring group that optionally has a substituent group.

In this way, it is possible to obtain the organic light emitting element with a fine luminous efficiency, durability, lifetime, electron injection property and electron transport property.

In this case, it is preferable that the Ar¹, Ar² and Ar³ in the chemical compound represented by the general formula (1) be a phenyl group that has a substituent group.

In this way, it is possible to obtain the organic light emitting element having a higher luminous efficiency, a better durability, a longer lifetime, a fine electron injection property and a fine electron transport property.

It is preferable that the substituent group of the Ar¹, Ar² and Ar³ be a group represented by the following general formula (2): 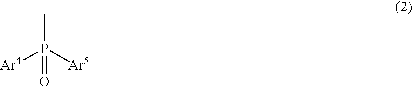
where Ar⁴ and Ar⁵ are each independently an aromatic ring group that optionally has a substituent group.

In this way, it is possible to obtain the organic light emitting element having a higher luminous efficiency, a better durability, a longer lifetime, a fine electron injection property and a fine electron transport property.

It is preferable that the Ar⁴ and Ar⁵ in the substituent group represented by the general formula (2) be a phenyl group.

In this way, it is possible to obtain the organic light emitting element having a higher luminous efficiency, a better durability, a longer lifetime, a fine electron injection property and a fine electron transport property.

It is preferable that a quantitative ratio “B/A” of the compound represented by the general formula (1) to the metal ion in the electron transport layer be 0.05 or more, where the number of P═O bonds in the compound represented by the general formula (1) is denoted as “A” and the number of the metal ion is denoted as “B”.

In this way, it is possible to improve the electron transport property and the durability of the element.

It is preferable that a quantitative ratio “B/A” of the compound represented by the general formula (1) to the metal ion in the electron transport layer be 0.2 or more, where the number of P═O bonds in the compound represented by the general formula (1) is denoted as “A” and the number of the metal ion is denoted as “B”.

In this way, the electron transport property and the durability of the element can be improved and it is possible to obtain the organic light emitting element having a higher luminous efficiency, a better durability, a longer lifetime, a fine electron injection property and a fine electron transport property.

Liquid material according to a third aspect of the invention includes a metal compound having at least one kind of a metal ion selected from an alkali metal ion, an alkali earth metal ion and a rare-earth metal ion, a solvent and a chemical compound represented by the following general formula (1): 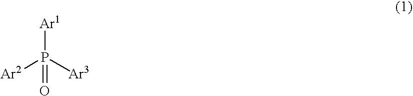
where Ar¹, Ar² and Ar³ are each independently an aromatic ring group that optionally has a substituent group.

In this way, it is possible to obtain a productive liquid material used for the production of the organic semiconductor element that has a high efficiency and a fine durability.

In this case, it is preferable that the solvent hardly swell or dissolve an organic light emissive layer.

In this way, where the liquid material is used for the formation of an organic semiconductor element, the quality alteration or the deterioration of an organic semiconductor thin film can be prevented and it can also prevent the film thickness from being too thin. Consequently, it is possible to obtain a highly productive liquid material used for the production of the organic semiconductor element that has a high efficiency and a fine durability.

It is preferable that the solvent be a polar-protonic solvent.

In this way, the decrease in the efficiency can be prevented and it is possible to obtain a highly productive liquid material used for the production of the organic semiconductor element that has a higher efficiency and a fine durability.

It is preferable that the solvent is mainly made of at least one of water and alcohols.

In this way, a metal ion can be assuredly dissociated from the metal ion and this facilitates the preparation of the liquid material. Accordingly, it is possible to obtain a highly productive liquid material used for the production of the organic semiconductor element that has a higher efficiency and a fine durability.

In this case, it is preferable that the alcohols be monohydric alcohols whose carbon number is 1-7.

The monohydric alcohols having such carbon number range have a high solubility of the metal compound. Consequently, it is possible to obtain a highly productive liquid material used for the production of the organic semiconductor element that has a higher efficiency and a fine durability.

It is preferable that the metal compound be mainly made of at least one of a metal salt, a metal complex and a metal alkoxide.

These metal compounds easily dissociate metal ions so that it is possible to obtain a highly productive liquid material used for the production of the organic semiconductor element that has a high efficiency and a fine durability.

It is preferable that the liquid material be prepared in such a way that a first solution containing the chemical compound represented by the general formula (1) and a second solution containing the metal compound are mixed.

In this way, the preparation of the liquid material containing the organic substance and the metal compound is facilitate and it is possible to obtain the highly productive liquid material used for the production of the organic semiconductor element that has a high efficiency and a fine durability.

It is also preferable that the liquid material be prepared in such a way that “B/A” becomes 0.05 or more where the number of P═O bonds in the compound represented by the general formula (1) is denoted as “A” and the number of the metal ion is denoted as “B”.

In this way, it is possible to obtain the highly productive liquid material used for the production of the organic semiconductor element that has a high efficiency and a fine durability.

It is preferable that the liquid material is prepared in such a way that “B/A” becomes 0.2 or more where the number of P═O bonds in the compound represented by the general formula (1) is denoted as “A” and the number of the metal ion is denoted as “B”.

In this way, it is possible to obtain the highly productive liquid material used for the production of the organic semiconductor element that has a high efficiency and a fine durability and a long lifetime.

A method for manufacturing an organic light emitting element according to a fourth aspect of the invention includes preparing a liquid material containing a metal compound that has at least one kind of a metal ion selected from an alkali metal ion, an alkali earth metal ion and a rare-earth metal ion, a solvent and a chemical compound represented by the following general formula (1): 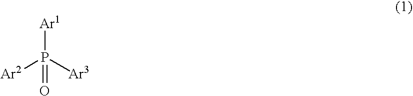
where Ar¹, Ar² and Ar³ are each independently an aromatic ring group that optionally has a substituent group, forming an electron transport layer by providing the liquid material onto an organic light emissive layer and drying the provided liquid material and forming a cathode on a side of the electron transport layer opposite to the organic light emissive layer.

In this way, it is possible to manufacture the organic semiconductor element having a fine luminous efficiency, durability, electron injection property and electron transport property with a high productivity.

In this case, it is preferable that the solvent hardly swell or dissolve the organic light emissive layer.

In this way, the quality alteration or the deterioration of the light emitting material of the organic light emissive layer can be prevented and it can also prevent the film thickness of the organic light emissive layer from being too thin. Consequently, it is possible to manufacture the organic semiconductor element having a finer luminous efficiency, durability, electron injection property and electron transport property with a higher productivity.

It is preferable that the solvent be a polar-protonic solvent.

In this way, the decrease in the luminous efficiency can be prevented and it is possible to manufacture the organic semiconductor element with a high productivity.

It is preferable that the solvent is mainly made of at least one of water and alcohols.

In this way, a metal ion can be assuredly dissociated from the metal ion and this facilitates the preparation of the liquid material. Accordingly, it is possible to manufacture the organic semiconductor element having a finer luminous efficiency, durability, electron injection property and electron transport property with a higher productivity.

In this case, it is preferable that the alcohols be monohydric alcohols whose carbon number is 1-7.

The monohydric alcohols having such carbon number range have a high solubility of the metal compound. Consequently, it is possible to manufacture the organic semiconductor element having a finer luminous efficiency, durability, electron injection property and electron transport property with a higher productivity.

It is preferable that the metal compound be mainly made of at least one of a metal salt, a metal complex and a metal alkoxide.

These metal compounds easily dissociate metal ions so that it is possible to manufacture the organic semiconductor element having a high efficiency, durability, electron injection property and electron transport property with a higher productivity.

It is preferable that the liquid material be prepared in such a way that a first solution containing the chemical compound represented by the general formula (1) and a second solution containing the metal compound are mixed.

In this way, the preparation of the liquid material containing the organic substance and the metal compound is facilitate and it is possible to manufacture the organic semiconductor element having a finer luminous efficiency, durability, electron injection property and electron transport property with a higher productivity.

It is also preferable that the liquid material be prepared in such a way that “B/A” becomes 0.05 or more where the number of P═O bonds in the compound represented by the general formula (1) is denoted as “A” and the number of the metal ion is denoted as “B”.

In this way, it is possible to manufacture the organic semiconductor element having a finer luminous efficiency, durability, electron injection property and electron transport property with a higher productivity.

It is preferable that the liquid material is prepared in such a way that “B/A” becomes 0.2 or more where the number of P═O bonds in the compound represented by the general formula (1) is denoted as “A” and the number of the metal ion is denoted as “B”.

In this way, it is possible to manufacture the organic semiconductor element having a finer luminous efficiency, durability, electron injection property and electron transport property with a higher productivity.

A light emitting device according to a fifth aspect of the invention includes the above described organic light emitting element. In this way, it is possible to obtain highly reliable light emitting device.

An electronic apparatus according to a sixth aspect of the invention includes the above mentioned light emitting device. In this way, it is possible to obtain highly reliable electronic apparatus.

### BRIEF DESCRIPTION OF THE DRAWINGS

The invention will be described with reference to the accompanying drawings, wherein like numbers reference like elements.

FIG. 1 is a schematic longitudinal sectional view of an organic light emitting element according to an embodiment of the invention.

FIG. 2 is a schematic longitudinal sectional view of a display device of an embodiment to which a light emitting device according to one aspect of the invention is applied.

FIG. 3 is a perspective view showing a structure of a mobile (or laptop) kind personal computer to which an electronic apparatus according to an aspect of the invention is applied.

FIG. 4 is a perspective view showing a structure of a cell-phone (including personal handyphone system: PHS) handset to which an electronic apparatus according to an aspect of the invention is applied.

FIG. 5 is a perspective view showing a structure of a digital still camera to which an electronic apparatus according to an aspect of the invention is applied.

### DESCRIPTION OF EXEMPLARY EMBODIMENTS

Organic-inorganic composite semiconductor material, liquid material, an organic light emitting element, a method for manufacturing an organic light emitting element, a light emitting device and an electronic apparatus according to embodiments of the invention will be now described with reference to the drawings.

### First Embodiment

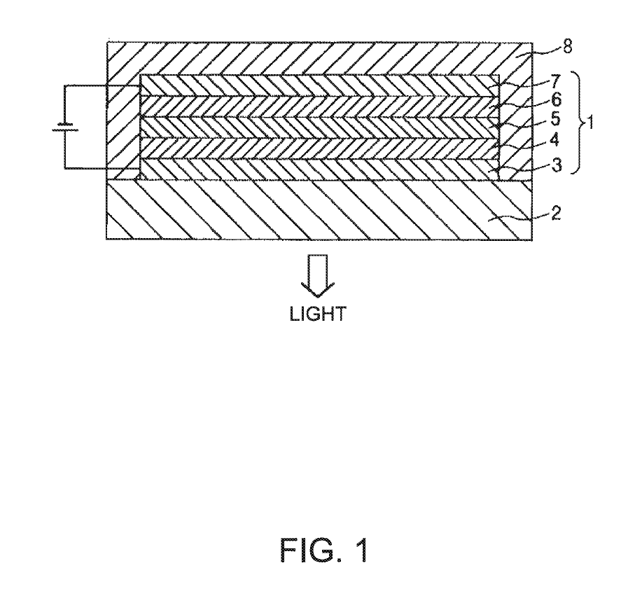

FIG. 1 is a schematic longitudinal sectional view of an organic light emitting element according to an embodiment of the invention. In the following description, the upper side in FIG. 1 is described as “upper side” and the lower side in the FIG. 1 is described as “lower side” for convenience of explanation.

An organic light emitting element 1 (an organic electroluminescence element) shown in FIG. 1 has an anode 3 provided on a substrate 2 and a cathode 7. A hole transfer layer 4 is provided on the anode 3 side, on top of which there is an organic emissive layer 5, and on top of which there is an electron transport layer 6 on the cathode 7 side between the anode 3 and the cathode 7. All of these elements are sealed with a sealing member 8.

The substrate 2 is a supporting member for the organic light emitting element 1. The light emitting element 1 in this embodiment has a structure (bottom-emission kind) in which light is drawn out from the substrate 2 side. Therefore, the substrate 2 and the anode 3 are substantially transparent (colorless and clear, colored but clear, or translucence).

As a constituent material for the substrate 2, for example, resin materials such as a polyethylene terephthalate, a polyethylene naphthalate, a polypropylene, a cycloolefin polymer, a polyamide, a polyether sulfone, a polymethyl methacrylate, a polycarbonate and a polyarilate, or glass materials such as a quartz glass and a soda glass and the like can be used. One of the above-mentioned material or combination thereof can also be used to form substrate.

Average thickness of the substrate 2 is not particularly limited. However, it is preferred that the thickness be within a range of around 0.1-30 mm, more preferably about 0.1-10 mm.

Where the organic light emitting element 1 has a structure (top-emission kind) in which light is drawn out from the side opposed to the substrate 2, either a transparent substrate or an opaque substrate can be adopted as the substrate 2.

As the opaque substrate, for example, a substrate made of ceramic material such as alumina, a metal substrate made of such as stainless steel and on which an oxide film (an insulating film) is formed, a substrate made of resin material and the like can be used.

The anode 3 is an electrode that injects electron holes into the hereinafter described hole transfer layer 4. It is preferred that the anode 3 be made of a material having a large work function and a high conductivity.

As a material for the anode 3, there are for example oxides such as an indium tin oxide (ITO), an indium zinc oxide (IZO), a In₃O₃, a SnO₂, a Sb-containing SnO₂ and an Al-containing ZnO; Au; Pt; Ag; Cu and alloys thereof. In addition, one or more than one of the above-mentioned materials combined can also be adopted.

An average thickness of the anode 3 is not particularly limited. However, it is preferred that the thickness be about 10-200 nm, more preferably, about 50-150 nm.

The cathode 7 is an electrode that injects electrons into the hereinafter described electron transport layer 6 and that is provided in the side opposite to the organic emissive layer 5. It is preferable that the cathode 7 be made of material with a small work function.

Examples of the material for the cathode 7 include Li, Mg, Ca, Sr, La, Ce, Er, Eu, Sc, Y, Yb, Ag, Cu, Al, Cs and Rb and alloys containing the above-mentioned material. In addition, one or more than one of the above-mentioned materials combined may also be adopted (for example, multi-layered member consisting of the above-mentioned materials).

Especially, where an alloy is used to form the cathode 7, an alloy containing a stable metal element such as Ag, Al and Cu is preferable. More specifically, alloys such as MgAg, AlLi and CuLi are preferable. In this way, it is possible to improve the electron injection efficiency and stability of the cathode 7.

An average thickness of the cathode 7 is not particularly limited. However, it is preferred that the thickness be around 100-10000 nm, more preferably about 200-500 nm.

In case of the top-emission kind, a transparent film made of a material having a small work function or an alloy containing such material is deposited about 5-20 nm thick, and a highly transparent conductive material such as the ITO is further deposited about 100-500 nm thick on top of it.

The organic light emitting element 1 in this embodiment is the bottom-emission kind so that the cathode 7 is not necessarily transparent.

The hole transfer layer 4 is provided on the anode 3. The hole transfer layer 4 carries a function of transferring the electron holes injected from the anode 3 to the organic emissive layer 5.

Examples of the constituent material for the hole transfer layer 4 include metal phthalocyanine or metal-free phthalocyanine based compounds such as a phthalocyanine, a copper phthaiocyanine (CuPc) and an iron phthalocyanine; polyallylamine; fuluorene-allylamine copolymer; fuluorene-bithiophene copolymer; poly (N-vinyl carbazole); polyvinyl pyrene; polyvinyl anthracene; polythiophene; polyalkylthiophene; polyhexylthiopheone; poly (p-phenylene vinylene); polythienylene vinylene; pyrene formaldehyde resin; ethylcarbazole formaldehyde resin and derivatives thereof. One or more of the above-mentioned chemical compounds combined can also be used to form the hole transfer layer 4.

Furthermore, a mixture of the above-mentioned chemical compounds can also be adopted. Specific example includes a poly (3,4-ethylenedioxythiphene/styreonoesulphonic acid) (PEDOT/PSS) and the like.

An average thickness of the hole transfer layer 4 is not particularly limited. However, it is preferred that the thickness be around 10-150 nm, more preferably about 50-100 nm.

The organic emissive layer 5 is provided on the hole transfer layer 4 which is in one side of the anode 3. Electrons from the hereinafter described electron transport layer 6 and electron holes from the hole transfer layer 4 are supplied (injected) into the organic emissive layer 5. The electron holes and the electrons recombine in the organic emissive layer 5, excitons are generated by the energy released by the recombination, and energy (fluorescence or phosphorescence) is released (emitted) when the excitons return to the ground state.

As examples of the constituent material for the organic emissive layer 5, there are benzene based compounds such as 1,3,5-tris (3-phenyl-6-tri-fluoromethyl) quinoxaline-2-yl) benzen (TPQ1) and 1,3,5-tris[{3-(4-t-butylphonyl)-6-trisfluoromethyl} quinoxaline-2-yl]benzene (TPQ2); low-molecular compounds such as tris (8-hydroxyquinoline) aluminum (Alq3) and fac tris (2-phenypyridine) iridium (Ir(ppy)₃); and macro-molecular compounds such as oxadiazole based polymers, triazole based polymers, carbazole based polymers, polyfluorene based polymers and polyparaphenylene vinylene based polymers. In addition, one or more of the above-mentioned materials combined can also be used to form the organic emissive layer a.

An average thickness of the organic emissive layer 5 is not particularly limited. However, it is preferred that the thickness be around 10-150 nm, more preferably about 50-100 nm.

The electron transport layer 6 is provided on the organic emissive layer 5. The electron transport layer 6 carries a function of transferring the electron injected from the cathode 7 to the organic emissive layer 5.

According to one aspect of the invention, the constituent of the electron transport layer 6 (particularly the organic-inorganic composite semiconductor material forming the layer) has a feature. This feature will be described later in detail.

An average thickness of the electron transport layer 6 is not particularly limited. However, it is preferred that the thickness be around 1-100 nm, more preferably about 10-50 nm.

The sealing member 8 is provided so as to cover the organic light emitting element 1 (the anode 3, the hole transfer layer 4, the organic emissive layer 5, the electron transport layer 6 and the cathode 7). The sealing member 8 seals these components in an air-proof manner and shields against oxygen and water. By providing the sealing member 8, such advantageous effects as improvement in the credibility of the organic light emitting element 1, prevention of alteration or deterioration (improvement of durability) and the like can be obtained.

As constituent material for the sealing member 8, for example, Al, Au, Cr, Nb, Ta, Ti and those alloys can be used. Oxide silicon, various kinds of resin materials and the like can also be used. Where a conductive material is adopted as the constituent material of the sealing member 8, an insulating film is preferably provided between the sealing member 8 and the organic light emitting element 1 if required in order to prevent short-circuit.

The sealing member 8 may be formed in a plate like shape and provided so as to oppose the substrate 2. In this case, a sealing material such as a thermo-setting resin, for example, is provided so as to seal between the substrate and the sealing member.

The inventors have keenly studied the ways to improve the electron transport capability of the electron transport layer 6 mainly made of an organic compound containing a phosphorus atom and the ways to improve the property and the durability of the organic light emitting element 1 formed by using the electron transport layer 6. As a result, the inventors have found out that light emitting properties (a rise in the luminance of the emission, a lowered driving voltage, an improvement in the luminous efficiency and the like) and the durability of the organic light emitting element 1 can be improved by mixing metal ions such as an alkali metal, an alkali earth metal, a rare-earth metal or the like into the electron transport layer 6 mainly made of a chemical compound represented by the following general formula (1): 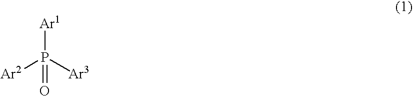
where Ar¹, Ar² and Ar³ are each independently an aromatic ring group that may have a substituent group.

Causes of the rise in the luminance of the emission and the lowered driving voltage are speculated as follows. Firstly, the metal ions existing around the boundary face between the electron transport layer 6 and the cathode 7 are reduced to a neutral mental with a lower work function when the cathode 7 is formed on the electron transport layer 6 by a vacuum deposition method or the like, this improves the injection efficiency of the electrons from the cathode 7 into the electron transport layer 6. Secondly, the energy level of the organic compound is relatively changed by a chemical interaction (ion bonding, coordinate bonding or the like) between the metal ion and the phosphorus atom in the compound of the general formula (1). It follows that a highest occupied molecular orbital (HOMO) and a lowest unoccupied molecular orbital (LUMO) move to relatively lower energy levels. With these factors, the electron injection barrier at the interface between the electron transport layer 6 and the cathode 7 is reduced and the electron injection efficiency is improved. Accordingly, the electrons are more efficiently injected into the organic emissive layer 5 and this seems to cause the rise in the luminance of the emission and the lowered driving voltage.

The improvement in the luminous efficiency may be caused mainly by the fact that the reduced level of the HOMO restrains the electron holes that were not recombined from being sent to the cathode 7, the electron holes are efficiently accumulated at the interface between the electron transport layer 6 and the organic emissive layer 5 and these accumulated electron holes can again contribute to the recombination.

As for the improvement in the durability, diffusion of the metal ion into the organic emissive layer 5 is controlled by the chemical interaction between the chemical compound of the general formula (1) and the metal ion, and this restrain quenching by the metal ion. Moreover, the structure of the organic compound can be stabilized by the chemical interaction, and deformation of the steric structure and the like can be prevented. This helps the electron transport (delivery). These factors seem to largely contribute to the stabilization of the electron transport layer 6 at the time of the driving.

The present invention has been made based on such findings, and one feature of the invention is that the electron transport layer 6 is mainly made of the material containing at least one kind of a metal ion from an alkali metal ion, an alkali earth metal ion and a rare-earth metal ion, and the chemical compound represented by the following general formula (1): 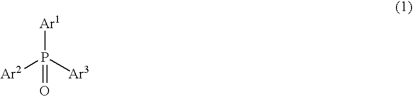
where Ar¹, Ar² and Ar³ are each independently an aromatic ring group that optionally has a substituent group.

Since the chemical compound represented by the general formula (1) has a phosphorus atom, it has an adequately high electronegativity and it is possible to incline electrons slightly toward the phosphorus atom in the structure of the compound. This helps to further enhance the chemical interaction between the metal ion and the compound of the general formula (1). Consequently, the structure of the compound of the general formula (1) can be further stabilized and the diffusion of the metal ion can be restrained. The phosphorus atom has an adequately high bond order so that it has an unpaired electron which interacts with the metal ion and it easily forms a bond with other elements.

Here, Ar¹, Ar² and Ar³ in the general formula (1) mutually independently denote an aromatic ring group that may have a substituent group.

A carbon number of the aromatic ring group is not particularly limited. However, it is preferably 2-20, more preferably 2-15.

Examples of the aromatic ring group include monocyclic aromatic hydrocarbon groups such as a benzene ring (a phenyl group); monocyclic heterocyclic groups such as a thiophene ring, a triazine ring, a furan ring, a pyrazine ring and a pyridine ring, a thiazole ring, an imidazole ring and a pyrimidine ring; condensed polycyclic aromatic hydrocarbon ring groups such as a naphthalene ring and an anthracene ring; condensed polycyclic heterocyclic groups such as a thieno[3,2-b]fran ring; ring-aggregated aromatic hydrocarbon groups such as a biphenyl ring and a terphenyl ring; and ring-aggregated heterocyclic groups such as a bithiophene ring and a bifuran ring; groups of aromatic rings and heterocycles combined such as an acridine ring, an isoquinoline ring, an indole ring, a carbazole ring, a carboline ring, a quinoline ring, a dibenzofuran furan ring, a cinnoline ring, a thionaphthene ring, a 1,10-phenanthroline ring, a phenothiazine ring, a purine ring, a benzofuran ring and a silol ring. A benzene ring (a phenyl group) is particularly preferred among the above-mentioned rings. In this way, the structure of the compound represented by the general formula (1) can be stabilized and it is possible to provide the organic light emitting element 1 with a fine luminous efficiency, durability, lifetime, electron injection property and electron transport property.

Examples of a substituent that can be bonded with such aromatic ring group include an alkyl group, a halogen atom, a cyano group, a nitro group, an amino group, an aryl group and a diarylphosphinyl group, an alkoxy group and a group represented by the following general formula (2): 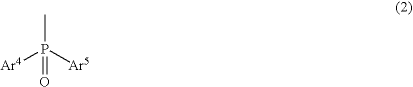
where Ar⁴ and Ar⁵ are each independently an aromatic ring group that may have a substituent group.

The compound represented by the general formula (2) is particularly preferable among the above-mentioned substituents. In this way, it is possible to provide the organic light emitting element 1 with a fine luminous efficiency, durability, lifetime, electron injection property and electron transport property.

A carbon number of an alkyl group is not particularly limited. However, it is preferably 1-20, more preferably 1-10. Examples include a methyl group, an ethyl group, a butyl group and a hexyl group. It can also form a substituted or unsubstituted aromatic ring together with the carbon atom of the benzene ring to which the substituent is coupled. In this way, the structure of the compound represented by the general formula (1) can be further stabilized. Examples of a substituent in case of the substituted aromatic ring include an alkyl group, an alkoxy group, a halogen atom, a cyano group, a nitro group, an amino group, an aryl group and a diarylphosphinyl group.

Examples of the halogen atom include a fluorine atom, a chlorine atom, a bromine atom, an iodine atom and the like.

Examples of the aryl group include aromatic hydrocarbon groups such as a phenyl group, a naphthyl group, a biphenyl group, a phenanthryl group, a terphenyl group and a pyrenyl group. These may be substituted or unsubstituted. As a substituent in case of the substituted aryl group, there are for example an alkyl group, an alkoxy group, a halogen atom, a cyano group, a nitro group, an amino group, an aryl group and a diarylphosphinyl group. The aryl of the diarylphosphinyl group includes the ones same as the above-mentioned examples of the aryl group

A carbon number of an alkoxyl group is not particularly limited. However, it is preferably 1-20, more preferably 1-10. Specific examples include include a methoxy group, an ethoxy group, a butoxy group, a pentoxy group and the like. In this way, the structure of the compound represented by the general formula (1) can be further stabilized.

Examples of Ar⁴ and Ar⁵ in the general formula (2) which is the aromatic ring group and examples of the substituent for the aromatic ring group are same as those described above referring Ar¹, Ar² and Ar³. However, a phenyl group is particularly preferable. In this way, the structure of the compound represented by the general formula (1) can be further stabilized and it is possible to provide the organic light emitting element 1 with a fine luminous efficiency, durability, lifetime, electron injection property and electron transport property.

Specific examples of the aromatic ring group for Ar¹, Ar² and Ar³ in the compound represented by the general formula (1), specific examples of the combination of the substituent for the aromatic ring group and specific examples of the compound of the general formula (1) are hereunder given. The following specific examples are only given by way of representative cases and examples are not particularly limited to these.

I. The chemical compound having a single substituent represented by the general formula (2) includes specific examples I-1 to 1-7 below.

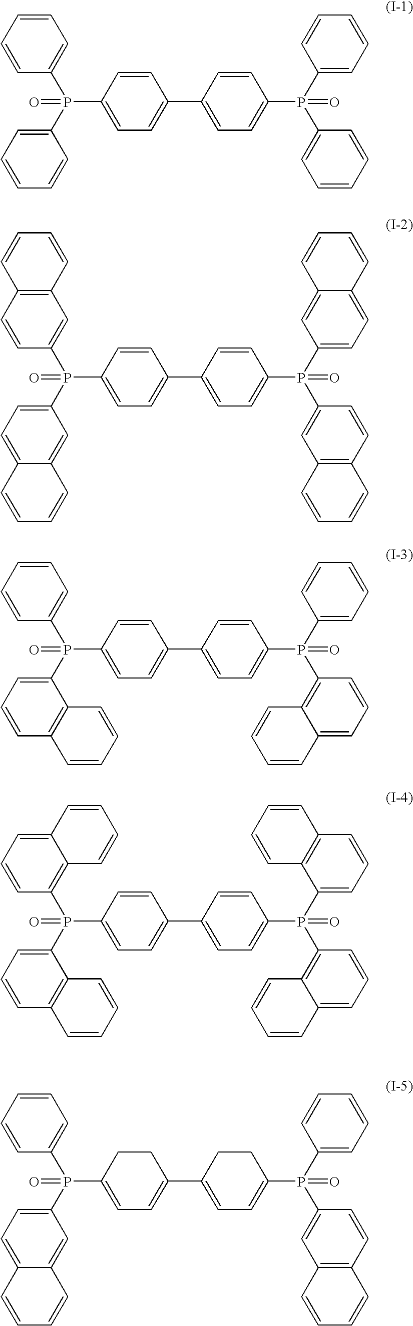

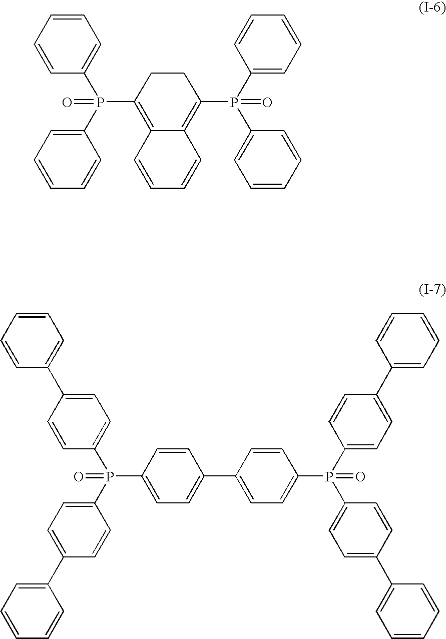

II. The chemical compound having two substituents represented by the general formula (2) includes specific examples 11-1 to II-21 below.

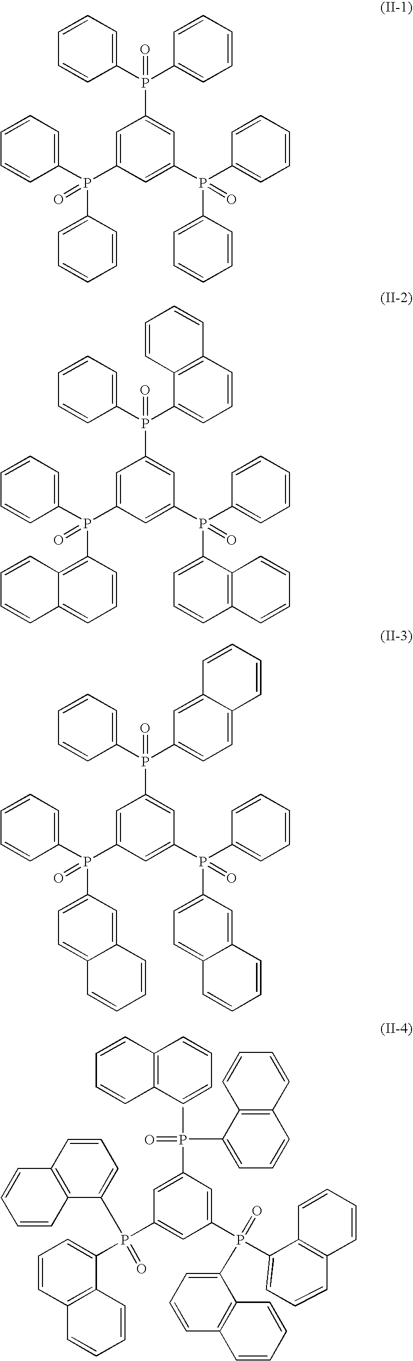

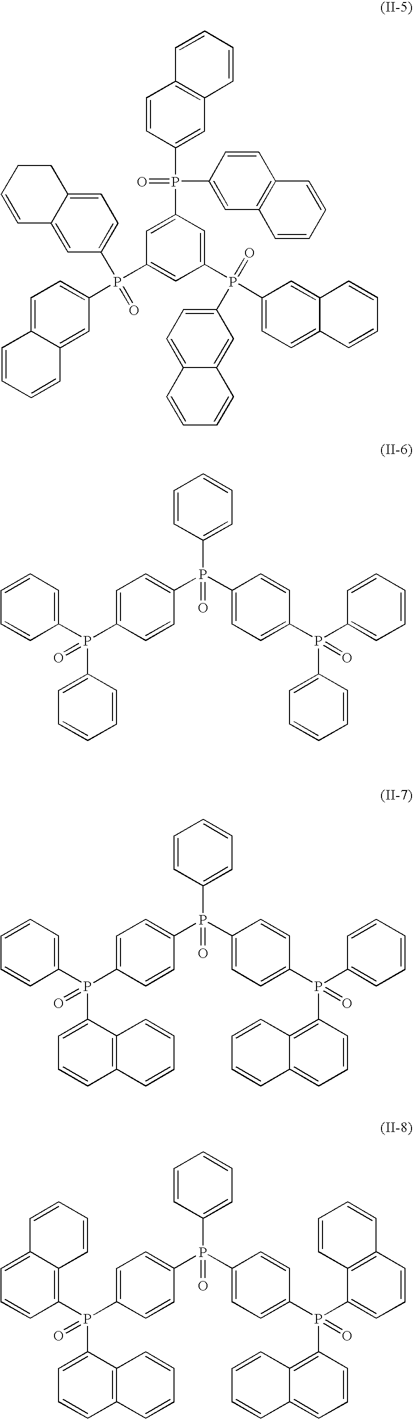

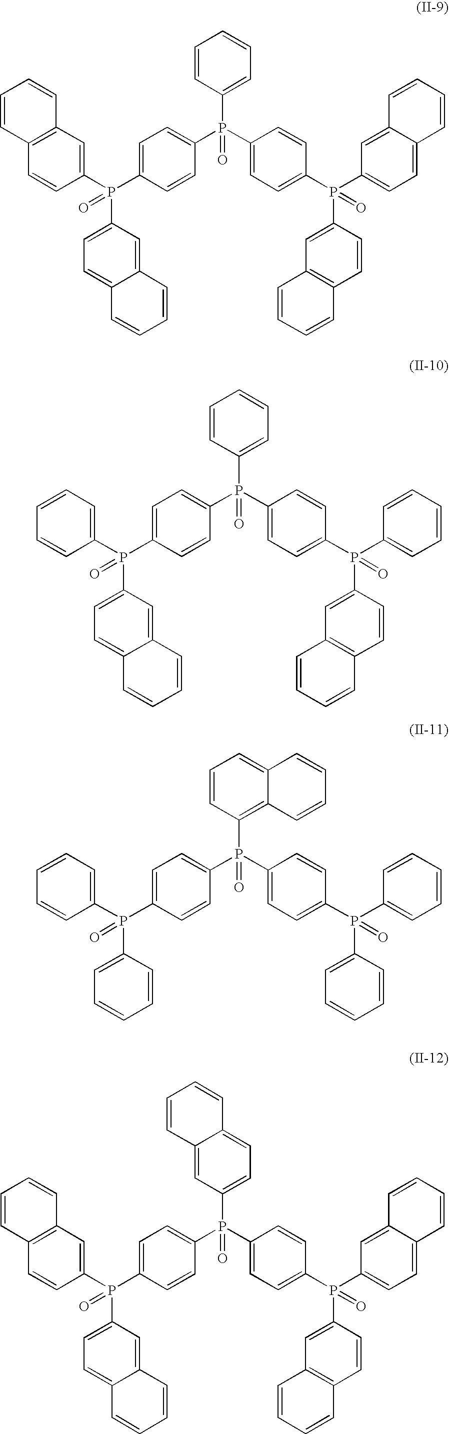

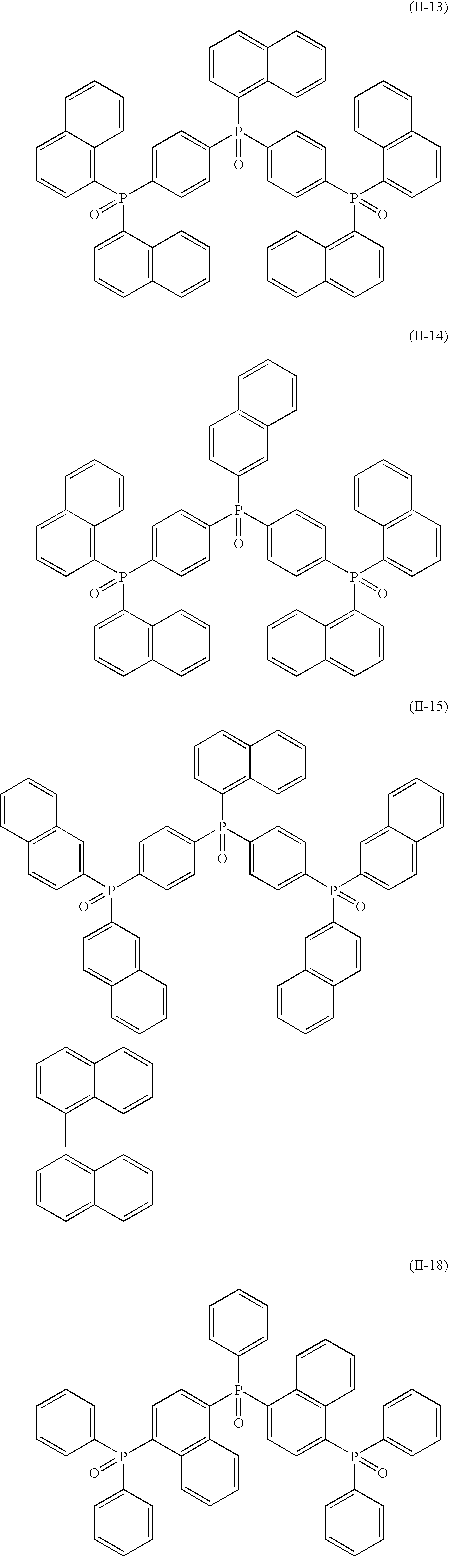

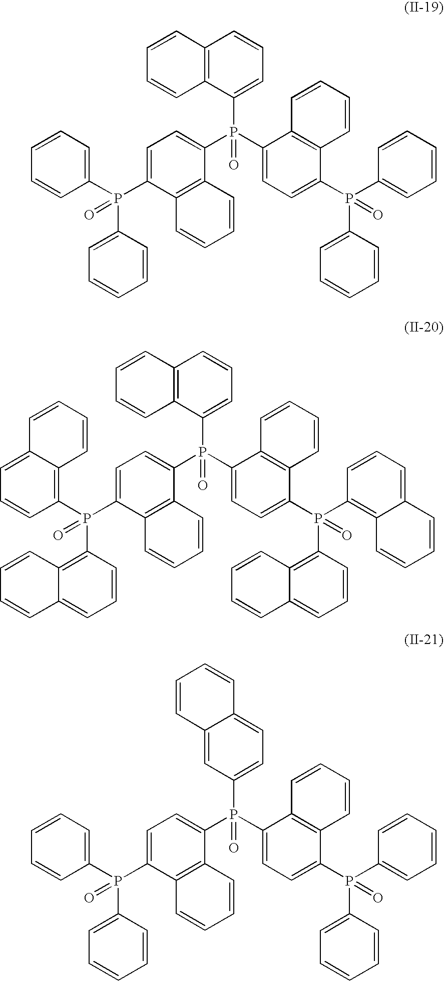

III. The chemical compound having three substituents represented by the general formula (2) includes specific examples III-1 to III-18 below

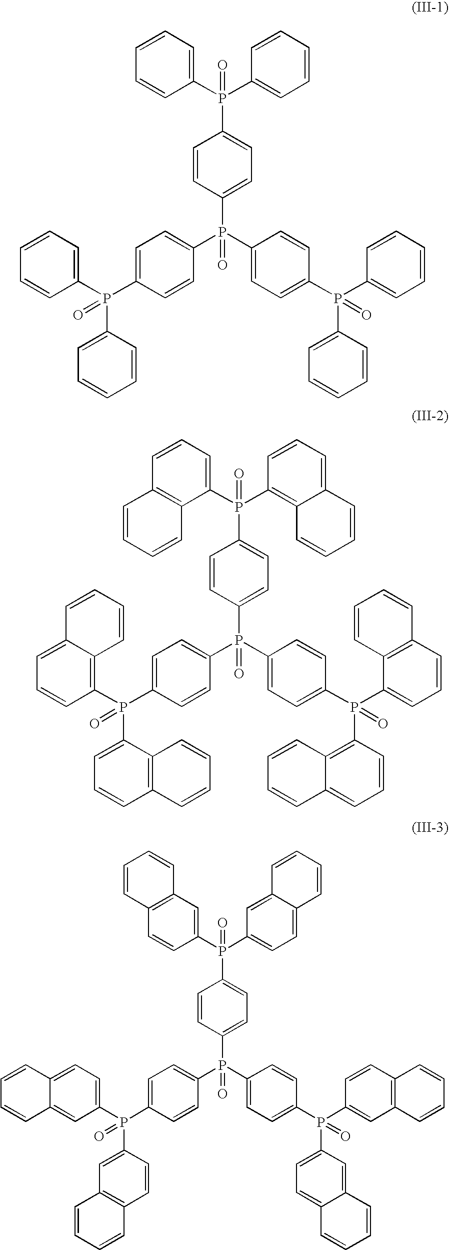

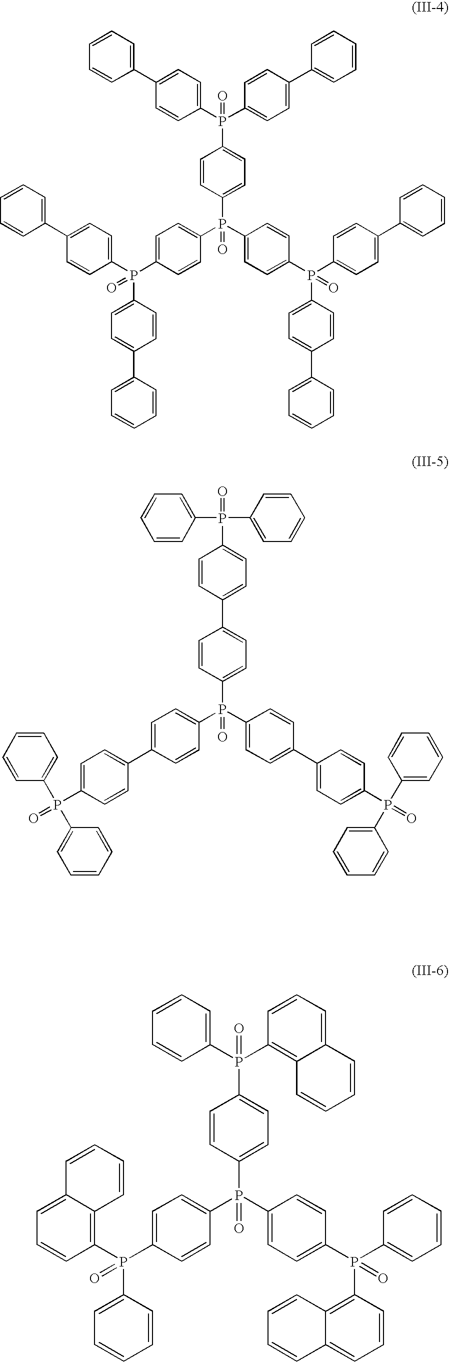

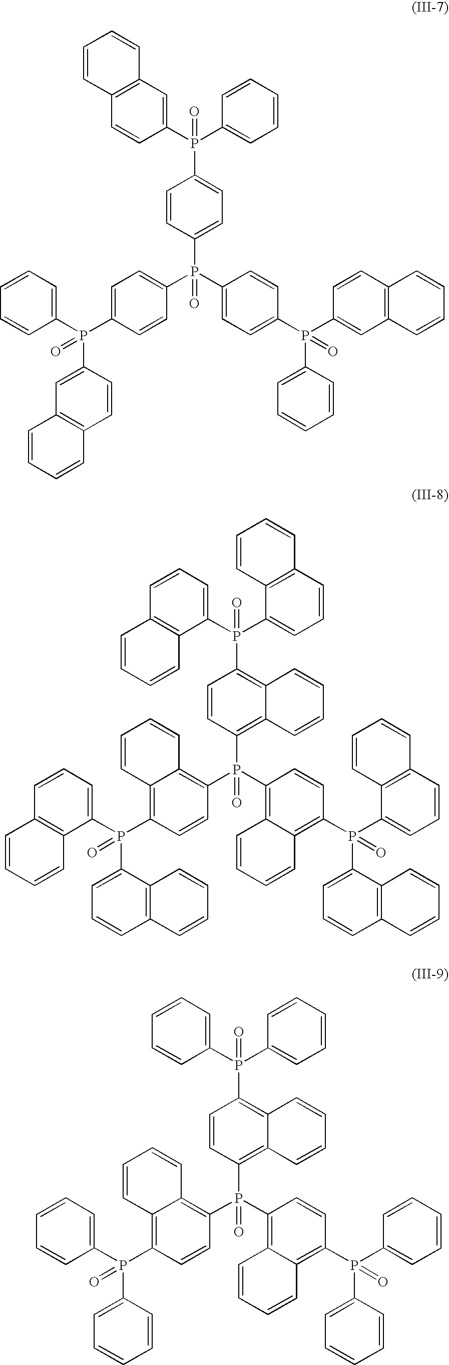

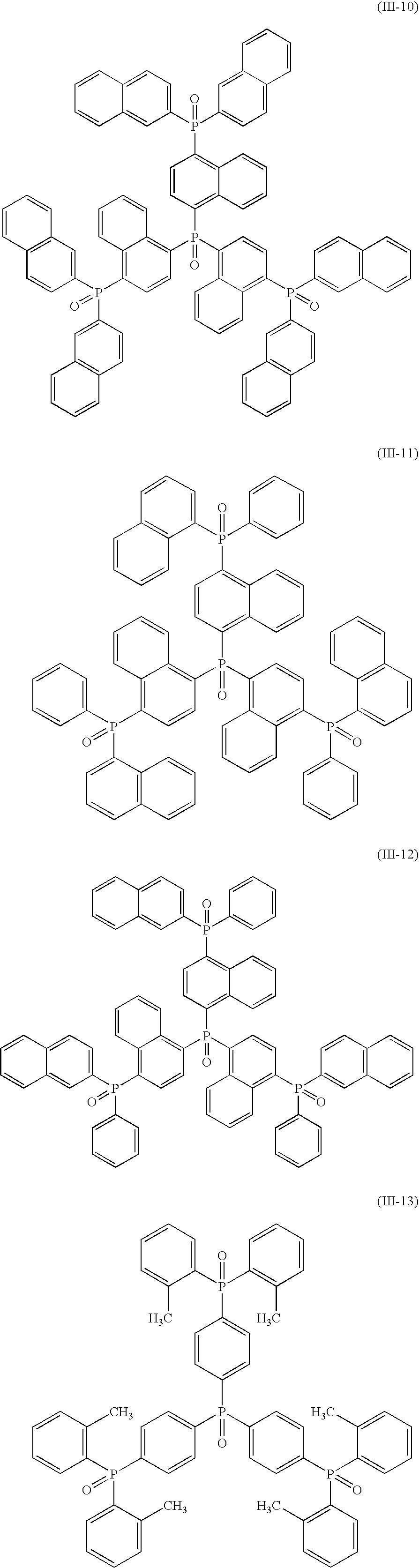

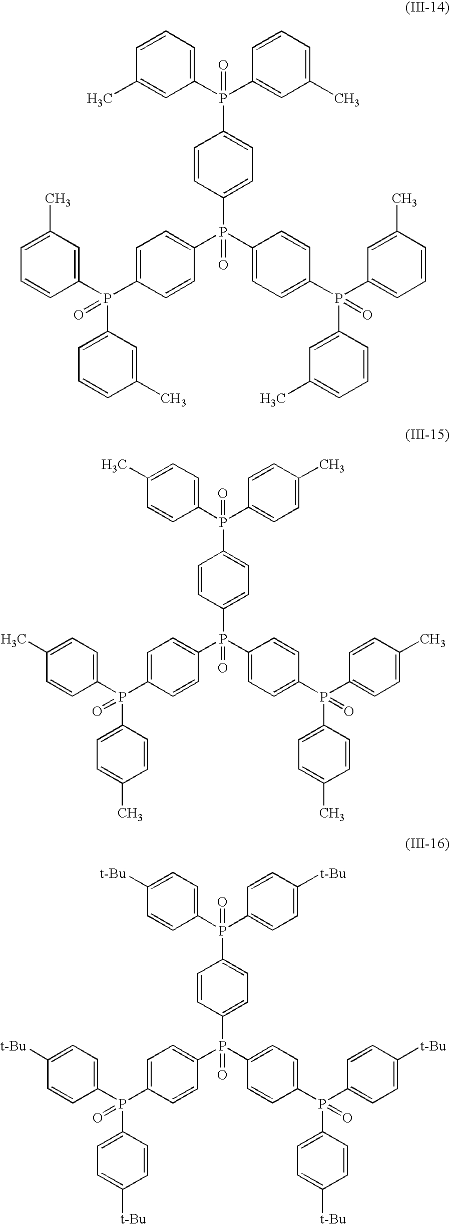

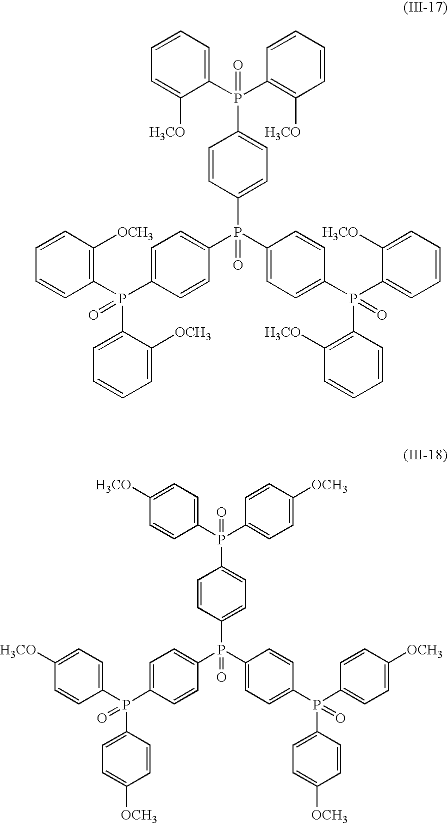

It is preferable that the content of the chemical compound represented by the general formula (1) with respect to the constituent material of the electron transport layer 6 be 30-700 wt %.

The compound represented by the general formula (1) can be synthesized by hitherto known methods, for example a method disclosed in Patent Publication WO2005/104628.

As for the metal ion, it should be selected according to the kind of the chemical compound of the general formula (1). It will be selected from an alkali metal ion such as Li, Na and K, an alkaline earth metal ion such as Mg, Ca and Sr, and a rare-earth metal ion such as Yb, Sc and Y. For example, where the chemical compound represented by the general formula (1) is one of the above specific examples 12 (or examples 13), metal ions such as Li, Cs, Ca, Mg and Yb are appropriate. More than one kind of metal ion may be used in combination.

It is preferable that the electron transport layer 6 be mainly made of the material containing at least one kind of the metal ion from the alkali metal ion, the alkali earth metal ion and the rare-earth metal ion and the chemical compound represented by the general formula (1). It is also preferable that the content of this material with respect to the whole constituent material of the electron transport layer 6 be 31-100 wt %, most preferably 50-100 wt %. In this way, the electron injection property and the electron transport property can be improved and it is possible to provide the organic light emitting element 1 with a fine luminous efficiency and durability.

As for a quantitative ratio of the compound of the general formula (1) to the metal ions in the electron transport layer 6, where the number of P═O bonds in the compound of the general formula (1) is denoted as “A” and the number of the metal ions is denoted as “B”, it is preferable that “B/A” is no smaller than 0.05, more preferably 0.2 or more, and most preferably about 0.2-1.5. By setting “B/A” in the above-mentioned range, just right amount of the metal ions can be allocated to the compound of the general formula (1) and it makes it possible to surely stabilize the structure of the compound represented by the general formula (1). This also makes it possible to sufficiently improve the injection efficiency of the electron injected from the cathode 7 to the electron transport layer 6 by the action of the metal ions. Therefore, the property of the electron transport layer 6 can be improved. Moreover, the number of the metal ions that do not chemically react with the compound of the general formula (1) can be sufficiently reduced and this makes it possible to securely prevent the metal ions from diffusing in the organic emissive layer 5. Accordingly, it is possible to adequately prevent the decrease in the emission luminance of the organic light emitting element 1 caused by aging and driving of the light emitting element 1.

Such material forming the electron transport layer 6 and containing at least one kind of the metal ion from the alkali metal ion, the alkali earth metal ion and the rare-earth metal ion and the chemical compound represented by the general formula (1) can also be used as the organic-inorganic composite semiconductor material.

In such a case, examples for the Ar¹, Ar² and Ar³ in the compound represented by the general formula (1), Ar⁴ and Ar⁵ in the general formula (2), respective substituents, and the alkali metal ion, the alkali earth metal ion and the rare-earth metal ion, the preferred embodiments thereof and the preferred material content are same as those described in the description of the electron transport layer 6.

As for a quantitative ratio of the compound of the general formula (1) to the metal ions in the organic-inorganic composite semiconductor material, the preferable value of “B/A” is also same as that of the electron transport layer 6 as described above where the number of P═O bonds in the compound of the general formula (1) is denoted as “A” and the number of the metal ions is denoted as “B”.

Such organic-inorganic composite semiconductor material has a fine electron injection property, electron injection property and durability and a long life so that it can be used as a semiconductor material for various devices.

Moreover, such material can also be used as various liquid materials when a solvent is added to the organic-inorganic composite semiconductor material. It is preferable that one which will not swell and dissolve the organic emissive layer 5 when added to the organic light emitting element 1 be used as such solvent. In this way, alteration and deterioration of the light emitting material and dissolution of the organic emissive layer 5 can be prevented and it is possible to prevent the thickness of the organic emissive layer 5 from being reduced. Consequently, it is possible to prevent the decrease in the luminous efficiency of the organic light emitting element 1.

Furthermore, one that can easily dissolve a metal compound and dissociate it into a metal ion is preferable as the solvent. More specifically, such solvent will be a polar-protonic solvent. Examples of such polar-protonic solvent include water; monohydric alcohols such as methanol, ethanol, propanol, butanol, benzyl alcohol and diethylene glycol monomethyl ether; polyhydric alcohols such as ethylene glycol and glycerine; carboxylic acid series such as acetic acid, formic acid and (meta-)acrylic acid; amine series such as ethylene diamine and diethylamine; amido series such as formamide and N,N-dimethyl formamide; phenol series such as phenol and p-butylphenol; active methylene compounds such as acetylacetone and diethyl malonate and the like. One or more than one above-mentioned compound combined can be used for the solvent.

It is preferable that at least one of water and alcohols be used as a main constituent of the solvent. Water and alcohols have a high solubility of metal compounds. Therefore, by using a solvent mainly made of at least one of water and alcohols as the polar-protonic solvent, the metal compound can be securely dissociated into a metal ion and this facilitates the preparation of the liquid material. As such alcohols, ones whose carbon number is 1-7 are preferable. More preferably, a monohydric alcohol whose carbon number is 1-4. Such monohydric alcohols having such carbon number range are preferred in terms of a high solubility of the metal compound. For example, where cesium carbonate (Cs₂CO₃) which is the metal compound is dissolved in a monohydric alcohol (R—OH), a Cs ion (the metal ion) is dissociated presumably through the following reaction:
Cs₂CO₃+2ROH→2Cs(OR)+CO₂+H₂O
Cs(OR)+H₂O→Cs⁺+OH⁻+ROH

The liquid material containing the organic-inorganic composite semiconductor material should be prepared in such a way that the relation between the compound of the general formula (1) and the metal ions in the obtained electron transport layer 6 becomes same as the above-mentioned relation where the number of P═O bonds in the compound of the general formula (1) is denoted as “A” and the number of the metal ions is denoted as “B”.

It is preferable that the metal compound having at least one kind of the metal ion from the alkali metal ion, the alkali earth metal ion and the rare-earth metal ion be a metal salt, a metal complex or a metal alkoxide. In this way, the metal ion can be easily dissociated and it is possible to obtain a highly productive liquid material used for the production of the organic semiconductor element that has a high efficiency and a fine durability. More than one kind of these metal compounds combined can also be used.

Examples of the metal salt, the metal complex and the metal alkoxide and those contents will be described in the following description of a manufacturing method for the organic light emitting element 1.

The above-described organic light emitting element 1 can be manufactured, for example, in the way as described below. The descriptions of the same elements and components described above will be hereunder omitted in the following explanation.

I. The substrate 2 is provided and the anode 3 is then formed on the substrate 2.

The anode 3 can be formed by applying, for example, chemical vapor deposition (CVD) methods such as a plasma CVD, a heat CVD and a laser CVD; a vacuum deposition method; a sputtering method; a dry plating method such as an ion-plating; wet plating methods such as an electrolytic plating, a dip plating and electroless plating; a spray method; a sol-gel method; a metal-organic deposition (MOD) method; bonding of a metal foil or the like.

II. The hole transfer layer 4 is formed on the anode 3. The hole transfer layer 4 can be formed by for example dissolving a forming material of the hole transfer layer into a solvent or dispersing the forming material of the hole transfer layer in a dispersion medium, providing it on the anode 3, and drying (removing the solvent or the dispersion medium) it.

Various methods can be used to apply the forming material of the hole transfer layer. There are for example a spin-coat method, a casting method, a micro-gravure coat method, a bar coat method, a roll coat method, a wire-bar coat method, a dip coat method, a spray coat method, a screen printing method, a flexographic printing method, an offset printing method, an ink-jet printing method and the like. According to these application methods, it is possible to facilitate the forming process of the hole transfer layer 4.

As the solvent or the dispersion medium used to prepare the material for forming the hole transfer layer, there are inorganic solvents such as nitric acid, sulfuric acid, ammonia, hydrogen peroxide, water, carbon disulfide, carbon tetrachloride and ethylene carbonate; ketone series solvents such as methyl-ethyl-ketone (MEK), acetone, diethylketone, methyl isobutyl ketone (MIBK), methyl isopropyl ketone (MIPK) and cyclohexane; alcohol series solvents such as methanol, ethanol, isopropanol, ethylene glycol, diethylene glycol (DEG) and glycerine; ether series solvents such as diethylether, diisopropylether, 1,2-dimethoxyethane (DME), 1,4-dioxan, tetrahydrofuran (THF), tetrahydropyran (THP), anisole, diethylene-glycol-dimethyl ether (diglyme) and diethylen-glycol-ethyl ether (carbitol); cellosolve series solvents such as methyl cellosolve, ethyl cellosolve and phenyl cellosolve. Furthermore, there are aliphatic hydrocarbon series solvents such as hexane, pentane, heptane and cyclohexane; aromatic hydrocarbon series solvents such as toluene, xylene and benzene, heteroaromatic compound series solvents such as pyridine, pyrazine, furan, pyrrole, thiophene and methylpyrrolidone; amid series solvents such as N,N-dimethyl formamide (DMF) and N,N-dimethyl acetamide (DMA); halogen compound series solvents such as chlorobenzene, dichloromethane, chloroform and 1,2-dichloroethane; ester series solvents such as acetic ether, methyl acetate and formic ether; sulfur compound series solvents such as dimethyl sulfoxide (DMSO) and sulfolane; nitrile series solvents such as acetonitrile, propionitrile and acrylonitrile; and organic acid solvents such as formic acid, acetic acid, trichloroacetic acid and trifluoroacetic acid and other various organic solvents. Mixed solvents containing the above-mentioned materials can also be used.

The drying can be performed by for example leaving the material in an atmosphere under an atmospheric pressure or a reduced pressure, a heating process, spraying of an inactive gas or the like.

Before the above-mentioned second process, the upper face of the anode 3 may be treated with oxygen plasma. This oxygen plasma treatment can impart hydrophilicity to the upper face of the anode 3 as well as removing (washing away) organic substances attached on the surface of the anode 3. Moreover, it is possible to adjust the work function around the upper face of the anode 3.

Conditions of the oxygen plasma treatment are set for example as follows: 100-800 W of plasma power, 50-100 ml/min of oxygen gas flow rate, 0.5-10 mm/sec of transport speed of the member (anode 3) receiving the treatment, and 70-90° C. of the temperature of the substrate 2.

III. The organic emissive layer 5 is then formed on the hole transfer layer 4 (on one side of the anode 3). The organic emissive layer 5 can be formed by for example dissolving a light emitting material into a solvent or dispersing the light emitting material in a dispersion medium, providing the obtained material for forming the organic emissive layer on the hole transfer layer 4, and drying (removing the solvent or the dispersion medium) it.

An application method and a drying method of the material for forming the organic emissive layer are the same as those described above in the description of the hole transfer layer 4 formation.

When the above-mentioned light emitting materials are adopted, apolar solvents are appropriate as the solvent or the dispersion medium to prepare the aterial for forming the organic emissive layer. As such apolar solvents, for example, there are aromatic hydrocarbon series solvents such as xylene toluene, cyclohexylbenzene, dihydrobenzofuran, trimethylbenzene and tetramethylbenzene; heteroaromatic compound series solvents such as pyridine, pyrazine, furan, pyrrole, thiophene and methylpyrrolidone; and aliphatic hydrocarbon series solvents such as hexane, pentane, heptane and cyclohexane. One of these material, or more than one material combined can also be used as the solvent.

IV. The electron transport layer 6 is then formed on the organic emissive layer 5.

IV-a: First Step

A liquid material containing the organic-inorganic composite semiconductor material which includes the metal ion and the above-mentioned chemical compound represented by the general formula (1) is prepared. The preparation can be preformed by mixing the metal compound which includes at least one of the alkali metal, the alkali earth metal and the rare-earth metal, the chemical compound of the general formula (1) and a solvent, and dissociating the metal compound into the metal ion.

Alternatively, a solution of the chemical compound of the general formula (1) and a solution of the metal ion can be separately prepared, and they are then mixed. In other words, a first solution containing the chemical compound of the general formula (1) and a second solution containing the metal compound are mixed. In this case, the respective solvents for these solutions do not have to be separated, and the kinds of these solutions may be different each other as long as they are mixable. In this way, the solubility of the chemical compound of the general formula (1) and the solubility of the metal compound will differ largely with respect to the same solvent, and the preparation of the solution becomes possible even with the case where it is difficult to obtain the solution with a desirable quantitative ratio. Furthermore, irrespective of the preparation methods for the liquid material described above, it is possible to mix the solution such that the above-mentioned “B/A” has a desired value in other words the value of “B/A” becomes same as the above-mentioned value given in the description of the liquid material. Consequently, it is possible to manufacture the organic light emitting element 1 having a fain luminous efficiency and durability with a high productivity.

Here, the metal compound is a compound having at least one of an alkali metal ion, an alkaline earth metal ion and a rare-earth metal ion. Example of such metal compound include metal salts of alkali metals such as Li, Na and K; alkaline earth metals such as Mg, Ca and Sr and rare-earth metals such as Yb, Sc and Y; salts of inorganic acids such as a carbonate salt, a nitrite salt and a sulfate salt; salts of organic acids such as an acetate and an acetyl acetate; halogenides such as a chloride salt and a bromide salt; metal alkoxides such as methoxide and ethoxide; metal complexes having a ligand which can be easily desorbed such as acetylacetonate and the like.

More specifically, as such metal compound, there are a cesium carbonate, a cesium acetate, a cesium chloride, a cesium acetylacetonate, a lithium carbonate, a lithium acetate, a lithium chloride, a lithium acetylacetonate, a ytterbium carbonate, a ytterbium acetate, a ytterbium chloride, a ytterbium acetylacetonate, a calcium carbonate, a calcium acetate, a calcium chloride, a calcium acetylacetonate and the like.

It is preferable that the metal compound is made of mainly one of the above-mentioned compound. Particularly, the cesium carbonate, the cesium acetate, the cesium chloride, the ytterbium chloride, the calcium chloride and the lithium acetylacetonate are preferred because these are relatively stable in the atmosphere and easy to handle and they easily dissociate metal ions. In this way, it is possible to manufacture the organic semiconductor element having a fine efficiency, durability, electron injection property and electron transport property with a high productivity.

It is preferable that the content of the metal compound in the electron transport layer 6 be 1-30 wt % with respect to the constituent material of the electron transport layer 6.

As for the solvents used to prepare the liquid material containing the organic-inorganic composite semiconductor material, it is preferable that ones which will hardly swell and dissolve the organic emissive layer 5 be used as the solvent. In this way, alteration and deterioration of the light emitting material and dissolution of the organic emissive layer 5 can be prevented and it is possible to prevent the thickness of the organic emissive layer 5 from being extremely reduced. Consequently, it is possible to prevent the decrease in the luminous efficiency of the organic light emitting element 1.

Furthermore, where the solution of the chemical compound of the general formula (1) and the solution of the metal compound are separately prepared, a solvent that can easily dissolve the metal compound and dissociate it into a metal ion is preferably as the solvent for the metal compound solution.

Considering such factors, a polar-protonic solvent is appropriate as the solvent. In this way, it is possible to prevent the luminous efficiency from being deteriorated and it is possible to manufacture the organic light emitting element 1 with a high productivity.

Examples of such polar-protonic solvent include water; monohydric alcohols such as methanol, ethanol, propanol, butanol, benzyl alcohol and diethylene glycol monomethyl ether; polyhydric alcohols such as ethylene glycol and glycerine; carboxylic acid series such as acetic acid, formic acid and (meta-)acrylic acid; amine series such as ethylene diamine and diethylamine; amido series such as formamide and N,N-dimethyl formamide; phenol series such as phenol and p-butylphenol; active methylene compounds such as acetylacetone and diethyl malonate and the like. One or more than one above-mentioned compound combined can be used for the solvent.

It is preferable that at least one of water and alcohols be used as a main constituent of the polar-protonic solvent. Water and alcohols have a high solubility of metal compounds. Therefore, by using a solvent mainly made of at least one of water and alcohols as the polar-protonic solvent, the metal compound can be securely dissociated into a metal ion and this facilitates the preparation of the liquid material containing the organic-inorganic composite semiconductor material.

As such alcohols, monohydric alcohols whose carbon number is 1-7 (more preferably 1-4) are preferable. Such monohydric alcohols having such carbon number range are preferred in terms of a high solubility of the metal compound. For example, where cesium carbonate (Cs₂CO₃) which is the metal compound is dissolved in a monohydric alcohol (R—OH), a Cs ion (the metal ion) is dissociated presumably through the following reaction:
Cs₂CO₃+2ROH→2Cs(OR)+CO₂+H₂O
Cs(OR)+H₂O→Cs⁺+OH⁻+ROH

The liquid material containing the organic-inorganic composite semiconductor material should be prepared in such a way that the relation between the compound of the general formula (1) and the metal ions in the obtained electron transport layer 6 in other words the value “B/A” is no smaller than 0.05, more preferably 0.2 or more, and most preferably about 0.2-1.5 where the number of P═O bonds in the compound of the general formula (1) is denoted as “A” and the number of the metal ions is denoted as “B”.

For example, the case where a compound represented by the following chemical formula 13 is adopted as the compound of the general formula (1), Cs₂CO₃ is used as the metal compound and the value “B/A” is 0.2 is described.

The chemical compound shown in the following chemical formula 13 has four P═O bonds whereas two Cs ions are dissociated from the Cs₂CO₃. In order to set the value “0.2” to the “B/A”, 0.4 mol of the Cs₂CO₃ is mixed with 1 mol of the compound of the formula 13.

Chemical Formula 13

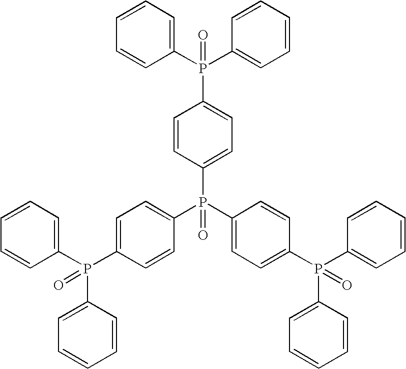

IV-b. Second Step

The prepared liquid material containing the organic-inorganic composite semiconductor material is provided on the organic emissive layer 5 and the material is then dried (the solvent is removed). In this way, the electron transport layer 6 made of the organic-inorganic composite semiconductor material is obtained. An application method and a drying method of the liquid material containing the organic-inorganic composite semiconductor material are the same as those described above in the description of the hole transfer layer 4 formation.

Subsequently, the cathode 7 is formed on the electron transport layer 6 (on the opposite side to the organic emissive layer 5).

IV-c Third Step

In this step, the cathode is formed on the side of the electron transport layer 6 which is opposite to the organic emissive layer a.

The cathode 7 can be formed by, for example, a vacuum deposition method, a sputtering method, bonding of a metal foil, application of metal particle ink, calcination and the like.

Through such steps, the light emitting element 1 can be obtained.

Finally, the sealing member 8 is overlaid so as to cover the light emitting element 1, and the sealing member 8 is then jointed to the substrate 2.

According to the above-described manufacturing method, the organic layers (the hole transfer layer 4, the organic emissive layer 5, the electron transport layer 6), and even the cathode 7 in case where a metal particle ink is used, can be formed without large scale equipment such as vacuum equipment. Therefore, it is possible to reduce the production time and the manufacturing cost of the light emitting element 1. Furthermore, where an ink-jet method (a droplet discharge method) is applied, it makes easy to form elements in a large area and to apply multiple color inks by color.

In the above described embodiments, the hole transfer layer 4 and the organic emissive layer 5 are formed by the liquid phase process. However, these layers can be made by a gas phase process depending on a kind of the hole transfer material and the light emitting material.

The above-described light emitting element 1 can be used as, for example, a light source and the like. If a plurality of the organic light emitting elements 1 is arranged in matrix, a display device (a light emitting device according to an aspect of the invention) can be formed.

A driving method of the display device is not particularly limited. Either an active matrix method or a passive matrix method can be applied.

Next, an example of the display device to which a light emitting device according to an aspect of the invention is applied will be described.

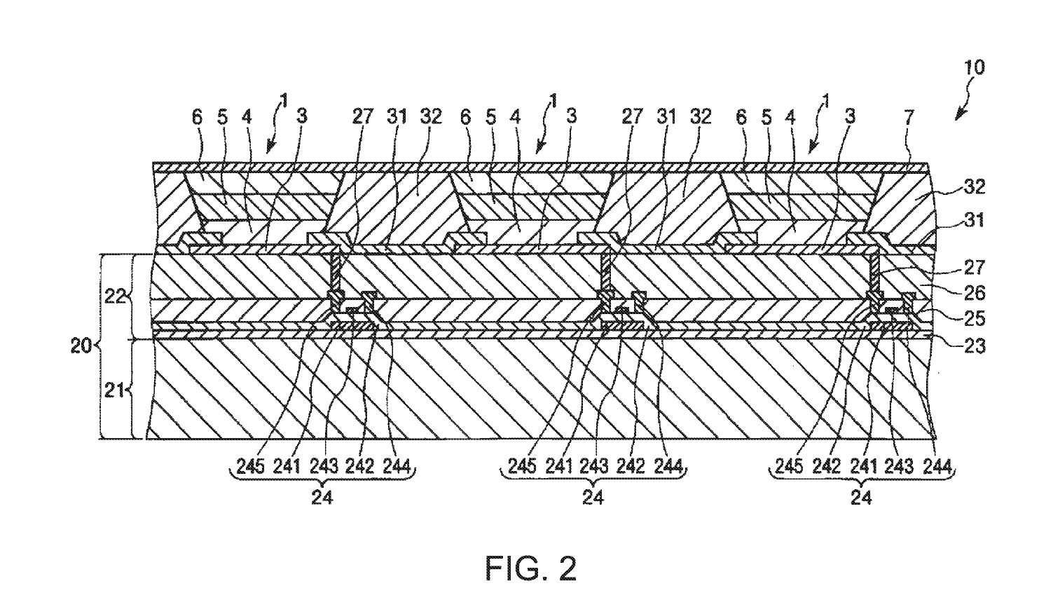

FIG. 2 is a schematic longitudinal sectional view of a display device of an embodiment to which a light emitting device according to one aspect of the invention is applied.

A display device 10 shown in FIG. 2 includes a base body 20 and the plurality of the light emitting elements 1 provided on the base body 20.

The base body 20 has a substrate 21 and a circuit part 22 formed on the substrate 21.

The circuit part 22 has a protection layer 23 that is made of for example an oxide silicon layer and formed on the substrate 21, a driving TFT 24 (a switching element) formed on the protection layer 23, a first interlayer insulating layer 25 and a second interlayer insulating layer 26.

The driving TFT 24 has a semiconductor layer 241 made of silicon, a gate insulating layer 242 formed on the semiconductor layer 241, a gate electrode 243 formed on the gate insulating layer 242, a source electrode 244 and a drain electrode 245.

The organic light emitting element 1 is provided corresponding to each driving TFT 24 above the circuit part 22. Two adjacent organic light emitting elements 1 are separated by a first separation wall part 31 and a first separation wall part 32.

In this embodiment, the anode 3 in each organic light emitting element 1 serves as a pixel electrode that is electrically coupled with the drain electrode 245 of the driving TFT 24 through a wiring 27. The cathode 7 in each light emitting element 1 is made as a common electrode.

Each light emitting element 1 is sealed with the sealing member (not shown in the drawings) which is jointed with the base body 20 so as to cover the light emitting element 1.

The display device 10 may be a monochrome display or a color display by selecting the light emitting material used for each organic light emitting element 1.

Such display device 10 (the light emitting device of the embodiment) may be embedded with various kinds of electronic equipment.

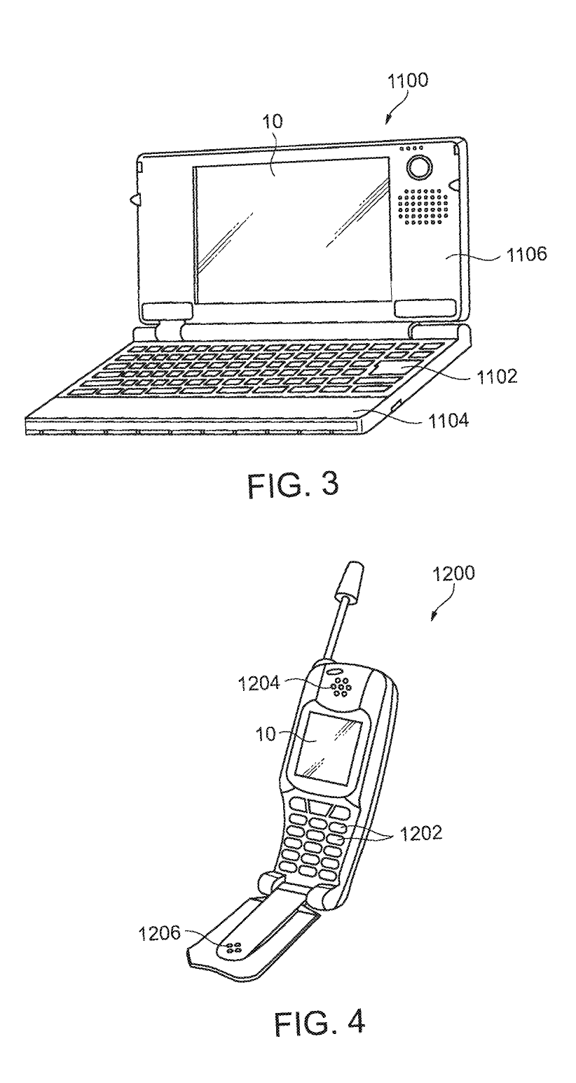

FIG. 3 is a perspective view showing a structure of a mobile (or laptop) kind personal computer to which an electronic apparatus according to an aspect of the invention is applied.

A personal computer 1100 includes a main body part 1104 having a keyboard 1102 and a display device unit 1106 having a display as shown in the figure. The display unit 1106 is supported rotatable by the computer body 1104 via a hinge mechanism.

The display part of the display device unit 1.106 is the above-described display device 10 in this personal computer 1100.

FIG. 4 is a perspective view showing a structure of a cell-phone (including personal handyphone system: PUS) handset to which an electronic apparatus according to an aspect of the invention is applied.

In FIG. 4, a cell-phone 1200 has a plurality of operation buttons 1202, an ear piece 1204 and a mouth piece 1206, and a display part.

The display part is the above-described display device 10 in this cell-phone 1200.

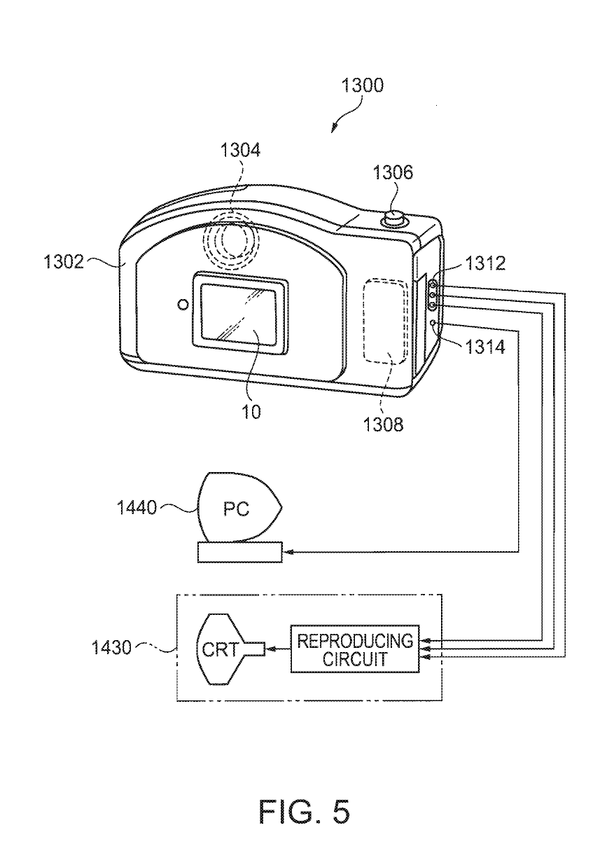

FIG. 5 is a perspective view showing a structure of a digital still camera to which an electronic apparatus of the invention is applied. Connections with external devices are also schematically shown in FIG. 5.

In contrast to ordinary cameras in which a silver salt photographic film is photosensitized by an optical image of an object, a digital still camera 1300 creates an image signal (picture signal) by photoelectrically converting the optical image of the object by an imaging element such as a CCD (charge coupled device).

A display part provided on the back face of a case (body) 1302 of the digital still camera 1300 display an image based on the signal imaged by the CCD, and the display part serves as a finder which displays the object as an electronic image.

The display part is the above-described display device 10 in this digital still camera 1300.

A circuit substrate 1308 is provided in the case. The circuit substrate 1308 has a memory that can store (memorize) the image signal.

A light receiving unit 1304 which includes an optical lens (imaging optics), the CCD and the like are provided on the front side (back side in FIG. 5) of the case 1302.

When a photographer looks the object image displayed on the display part and presses the shutter button 1306, the image signal of the CCD at that moment is transferred to the memory on the circuit substrate 1308 and is stored therein.

In the digital still camera 1300, a video signal output terminal 1312 and an input/output terminal 1314 are provided on a side face of the case 1302. Besides, as shown in FIG. 5, a television monitor 1430 and a personal computer 1440 are connected to the video signal output terminal 1312 and the input/output terminal 1314 for data communication, respectively, as needed. Moreover, the system is configured such that imaged signals stored in the memory of the circuit substrate 1308 are outputted to the television monitor 1430 or the personal computer 1440 by a predetermined operation.

Other examples of the electronic apparatus according to the aspect of the invention include, besides the personal computer (mobile kind personal computer) in FIG. 3, the cell-phone in FIG. 4 and the digital still camera in FIG. 5, a television, a video camera, a viewfinder kind or a monitor-direct kind video tape recorder, a laptop personal computer, a car navigation device, a pager, an electronic notebook (including one with communication function), an electronic dictionary, a desktop calculator, an electronic game machine, a word processor, a work station, a video telephone, a crime prevention video monitor, an electronic binocular, a Point of Sale (POS) terminal, medical equipment (for example, an electronic clinical thermometer, a blood pressure gauge, a blood sugar meter, an electrocardiogram measurement instrument, ultrasonic diagnostic equipment and an electronic endoscope), a fish finder, various kinds of measurement equipment, instruments (for example, instruments for trains, aircrafts and ships), a flight simulator, other various kinds of monitors, a projection kind display device such as a projector and the like.

The organic-inorganic composite semiconductor material, the liquid material, the organic light emitting element, the method for manufacturing an organic light emitting element, the light emitting device and the electronic apparatus according to the aspects of the invention have been fully described by way of examples with reference to the accompanying drawings, and it is to be understood that the embodiments described above do not in any way limit the scope of the invention.

For example, the organic light emitting element may further include at least one additional layer or more than one additional layer of any purposes between the above-mentioned layers described in the above embodiments.

Hereinafter, specific working examples according to the aspects of the invention will be described.

Fabrication of the organic light emitting element

### EXAMPLE 1

1. A transparent glass substrate having 0.5 mm of the average thickness was prepared.

2. An ITO electrode (the anode) having 100 nm of the average thickness was formed on the substrate by a sputtering method. The substrate was sequentially immersed into acetone and 2-propanol in this order, and then an ultrasonic cleaning was performed.

3. Aqueous dispersion liquid of a poly (3,4-ethylenedioxythiphene/styrenesulphonic acid) (PEDOT/PSS) was applied onto the ITO electrode by a spin-coat method. Subsequently, the substrate was dried with a hotplate that was heated to 200° C. under the atmospheric pressure for 10 minutes. Through this process, the hole transfer layer having 60 nm of the average thickness was formed.

4. Next, a monochlorobenzene solution in which polyvinyl carbazole and fac tris (2-phenypyridine) iridium were dissolved was applied on the hole transfer layer by a spin-coat method and then dried. In this way, the organic light emissive layer having 70 nm of the average thickness was formed. The blending ratio of the monochlorobenzene to the fac tris (2-phenypyridine) iridium was 97:3 by weight.

5. Cesium carbonate (Cs₂CO₃) which is the metal compound was dissolved into 2-plopanol. This solution was then added to 4,4′,4″-tris (diphenyl phosphinyl)-triphenylphosphine oxide (hereinafter referred as “TPPO-Burst”), and this added solution was diluted with 2-propanol so as to obtain a 0.5 wt % TPPO-Burst solution. In this way, the forming material for the electron transport layer was obtained.

Here, the blend ratio of the TPPO-Burst to the cesium carbonate was 2:1 of a molar ratio. It follows that the above-mentioned value of “B/A” was 0.25. The prepared forming material of the electron transport layer was then applied onto the organic light emissive layer by the spin-coat method, dried with a hotplate that was heated to 130° C. under the atmospheric pressure for 10 minutes. Through this process, the electron transfer layer having 15 nm of the average thickness was formed.

6. An Al electrode (the anode) having 200 nm of the average thickness was formed on the electron transport layer by a vacuum deposition method.

Finally, a protection cover (sealing member) made of glass was placed so as to cover the formed layers, the cover was then fixed with an epoxy resin and the formed layers were sealed.

### EXAMPLE 2

The organic light emitting element was fabricated in the same manner as the above-described way except that the blend ratio of the TPPO-Burst (the compound shown in chemical formula 13) to the cesium carbonate was 10:1 of the molar ratio in other words that the above-mentioned value of “BLA” was 0.05.

### EXAMPLE 2

The organic light emitting element was fabricated in the same manner as the above-described Example 1 except that the blend ratio of the TPPO-Burst (the compound shown in chemical formula 13) to the cesium carbonate was 10:1 of the molar ratio in other words that the above-mentioned value of “EVBA” was 0.05 in the above-described step 5.

### EXAMPLE 3

The organic light emitting element was fabricated in the same manner as the above-described Example 1 except that the blend ratio of the TPPO-Burst (the compound shown in chemical formula 13) to the cesium carbonate was 5:1 of the molar ratio in other words that the above-mentioned value of “B/A” was 0.1 in the above-described step 5.

### EXAMPLE 4

The organic light emitting element was fabricated in the same manner as the above-described Example 1 except that the blend ratio of the TPPO-Burst (the compound shown in chemical formula 1.3) to the cesium carbonate was 1:1 of the molar ratio in other words that the above-mentioned value of “B/A” was 0.5 in the above-described step 5.

### EXAMPLE 5

The organic light emitting element was fabricated in the same manner as the above-described Example 1 except that the blend ratio of the TPPO-Burst (the compound shown in chemical formula 13) to the cesium carbonate was 1:2 of the molar ratio in other words that the above-mentioned value of “B/A” was 1.0 in the above-described step 5.

### EXAMPLE 6

The organic light emitting element was fabricated in the same manner as the above-described Example 1 except that lithium acetylacetonate (Li [acac]) was used as the metal compound and the blend ratio of the TPPO-Burst (the compound shown in chemical formula 13) to the lithium acetylacetonate was 1:1 of the molar ratio in other words that the above-mentioned value of “B/A” was 0.25 in the above-described step 5.

### EXAMPLE 7

The organic light emitting element was fabricated in the same manner as the above-described Example 1 except that cesium chloride was used as the metal compound and the blend ratio of the TPPO-Burst (the compound shown in chemical formula 13) to the cesium carbonate was 1:1 of the molar ratio in other words that the above-mentioned value of “B/A” was 0.25 in the above-described step 5.

### EXAMPLE 8

The organic light emitting element was fabricated in the same manner as the above-described Example 1 except that cesium acetate was used as the metal compound and the blend ratio of the TPPO-Burst (the compound shown in chemical formula 13) to the cesium acetate was 1:1 of the molar ratio in other words that the above-mentioned value of “B/A” was 0.25 in the above-described step 5.

### EXAMPLE 9

The organic light emitting element was fabricated in the same manner as the above-described Example 1 except that calcium chloride (CaCl₂) was used as the metal compound and the blend ratio of the TPPO-Burst (the compound shown in chemical formula 13) to the calcium chloride was 1:1 of the molar ratio in other words that the above-mentioned value of “B/A” was 0.25 in the above-described step 5.

### EXAMPLE 10

The organic light emitting element was fabricated in the same manner as the above-described Example 1 except that ytterbium chloride (YbCl3) was used as the metal compound and the blend ratio of the TPPO-Burst (the compound shown in chemical formula 13) to the ytterbium chloride was 1:1 of the molar ratio in other words that the above-mentioned value of “B/A” was 0.25 in the above-described step a.

### COMPARATIVE EXAMPLE 1

The organic light emitting element was fabricated in the same manner as the above-described Example 1 except that the cesium carbonate was not blended in the above-described step 5.

### COMPARATIVE EXAMPLE 2

The organic light emitting element was fabricated in the same manner as the above-described Example 1 except that the electron transport layer was formed by co-deposition of the TPPO-Burst and the cesium carbonate and the blend ratio of the TPPO-Burst (the compound shown in chemical formula 13) to the cesium carbonate was 2:1 of the molar ratio in other words that the above-mentioned value of “B/A” was 0.05 in the above-described step 5.

Evaluation

1. Confirmation of the Existence of the Metal Ion

Before the formation of the Al electrode in each example and comparative example, the electron state of the metal existing in the electron transport layer was checked by an X-ray photoelectron spectroscopy method (XPS method). The X-ray photoelectron spectroscopy method was performed by the XPS equipment (“Quantera SXM” manufactured by Physical Electronics (PHI)).

The existence of the metal ions in the electron transport layer was confirmed in every above-described example.

2. Evaluation of the Luminous Efficiency

The values of the current and the luminance when 8 V of the voltage was applied between the anode and the cathode were measured with respect to each organic light emitting element fabricated in the above-described examples. The luminous efficiency [cd/A] was calculated from these measured values.

3. Evaluation of the Durability

Constant-current driving with 400 Cd/m² of the initial luminance was performed by applying a voltage from a direct current power source between the anode and the cathode with respect to each organic light emitting element fabricated in the above-described examples. A time period in which the luminance is halved compared to the initial luminance (the half life) was measured.

Results of the evaluations of the luminous efficiency and the durability are listed below.

TABLE 1

| | electron Transport Layer | | | | | |
|---|---|---|---|---|---|---|
| | | | | | Evaluation | |
| | Compound | | | | Result of | Evaluation |
| | of | | | | Luminous | Result of |
| | General | | | Film | Efficiency | Durability |
| | formula | Metal | | Forming | (relative | (relative |
| | (1) | Compound | B/A | Method | value) | value) |
| Example 1 | TPPO- | cesium | 0.25 | Liquid phase | 1.5 | 3.0 |
| | Burst | carbonate | | | | |
| Example 2 | TPPO- | cesium | 0.05 | Liquid phase | 1.1 | 1.1 |
| | Burst | carbonate | | | | |
| Example 3 | TPPO- | cesium | 0.1 | Liquid phase | 1.1 | 1.2 |
| | Burst | carbonate | | | | |
| Example 4 | TPPO- | cesium | 0.5 | Liquid phase | 1.5 | 2.8 |
| | Burst | carbonate | | | | |
| Example 5 | TPPO- | cesium | 1.0 | Liquid phase | 1.5 | 2.6 |
| | Burst | carbonate | | | | |
| Example 6 | TPPO- | lithium | 0.25 | Liquid phase | 1.3 | 2.0 |
| | Burst | acetyl- | | | | |
| | | acetonate | | | | |
| Example 7 | TPPO- | cesium | 0.25 | Liquid phase | 1.8 | 1.5 |
| | Burst | chloride | | | | |
| Example 8 | TPPO- | cesium | 0.25 | Liquid phase | 1.5 | 1.3 |
| | Burst | acetate | | | | |
| Example 9 | TPPO- | calcium | 0.25 | Liquid phase | 1.2 | 1.5 |
| | Burst | chloride | | | | |
| Example 10 | TPPO- | ytteribium | 0.25 | Liquid phase | 1.4 | 1.6 |
| | Burst | chloride | | | | |
| Comparative | TPPO- | — | 0 | Liquid phase | 1 | 1 |
| Example 1 | Burst | | | | | |
| Comparative | TPPO- | cesium | 0.05 | Gas phase | 1 | 1 |
| Example 2 | Burst | carbonate | | (codeposition) | | |

Evaluation results of Examples 1-10 in Table 1 are shown in a relative value with which the results of Comparative Example 1 and Comparative Example 2 are evaluated as “1”

As shown in Table 1, the organic light emitting elements fabricated in each example have a fine luminous efficiency and a fine durability.

In contrast, the organic light emitting elements fabricated in the comparative examples are inferior in the luminous efficiency and the durability to the organic light emitting elements manufactured according to the aspects of the invention.

The entire disclosure of Japanese Patent Application No: 2006-102556, filed Apr. 3, 2006 is expressly incorporated by reference herein.

What is claimed is:

1. Organic-inorganic composite semiconductor material, comprising:
at least a metal ion selected from an alkali metal ion, an alkali earth metal ion and a rare-earth metal ion; and
a chemical compound represented by the following general formula (1): 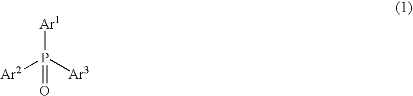
each of the Ar¹, Ar² and Ar³ having an aromatic ring group.

2. The organic-inorganic composite semiconductor material according to claim 1, at least one of the Ar¹, Ar² and Ar³ having a substituent group.

3. The organic-inorganic composite semiconductor material according to claim 1, the each of the Ar¹, Ar² and Ar³ having a phenyl group and a substituent group.

4. The organic-inorganic composite semiconductor material according to claim 1, the each of the Ar¹, Ar² and Ar³ having at least a phenyl group and a substituent group, the phenyl group being bonded to the P, the substituent group being bonded to the phenyl group, the substituent group represented by the following general formula (2): 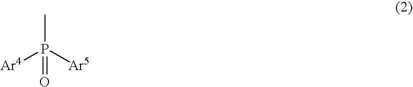
each of the Ar⁴ and Ar⁵ having at least an aromatic ring group.

5. The organic-inorganic composite semiconductor material according to claim 4, the each of the Ar⁴ and Ar⁵ having a phenyl group.

6. The organic-inorganic composite semiconductor material according to claim 1, a quantitative ratio “B/A” of the compound represented by the general formula (1) to the metal ion being 0.05 or more, the number of P═O bonds in the chemical compound represented by the general formula (1) being denoted as “A” and the number of the metal ion being denoted as “B”.

7. The organic-inorganic composite semiconductor material according to claim 1, a quantitative ratio “B/A” of the compound represented by the general formula (1) to the metal ion being 0.2 or more, the number of P═O bonds in the chemical compound represented by the general formula (1) being denoted as “A” and the number of the metal ion being denoted as “B”.

8. An organic light emitting element, comprising:
an anode;
a cathode;
an organic light emissive film interposed between the anode and the cathode; and
an electron transport film interposed between the organic light emissive layer and the cathode, the electron transport layer including the organic-inorganic composite semiconductor material according to claim 1.

9. The organic light emitting element according to claim 8, the electron transport film being formed by applying a liquid material to the organic emissive film, the liquid material including a metal compound having the metal ion, a solvent and the chemical compound represented by the general formula (1).

10. Liquid material, comprising:
a metal compound having at least a metal ion selected from an alkali metal ion, an alkali earth metal ion and a rare-earth metal ion;
a solvent; and
a chemical compound represented by the following general formula (1). 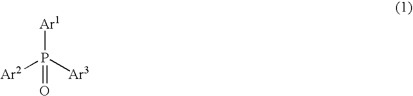
each of the Ar¹, Ar² and Ar³ having an aromatic ring group.

11. The liquid material according to claim 10, the solvent being a polar-protonic solvent.

12. The liquid material according to claim 10, the solvent including at least one of water and alcohols.

13. The liquid material according to claim 10, the solvent including monohydric alcohols whose carbon number is 1-7.

14. The liquid material according to claim 10, the metal compound including at least one of a metal salt, a metal complex and a metal alkoxide.

15. A light emitting device, comprising:
the organic light emitting element according to claim 8.

16. An electronic apparatus, comprising:
the light emitting device according to claim 15.

17. A method of manufacturing an organic light emitting element, comprising:
forming an organic light emissive layer over an anode;
forming an electron transport layer by providing the liquid material according to claim 10 to the organic light emissive layer; and
forming a cathode over the electron transport layer.
